(19) United States
(12) Patent Application Publication
(10) Pub. No.: US 2025/0040401 A1
(43) Pub. Date: Jan. 30, 2025

(54) DISPLAY PANEL

(71) Applicant: Hefei Visionox Technology Co., Ltd., Hefei (CN)

(72) Inventors: Yuan YAO, Hefei (CN); Chung-Chun LEE, Hefei (CN); Yiming XIAO, Hefei (CN); Liusong NI, Hefei (CN); Xiaojuan XUE, Hefei (CN)

(73) Assignee: Hefei Visionox Technology Co., Ltd., Hefei (CN)

(21) Appl. No.: 18/731,820

(22) Filed: Jun. 3, 2024

Related U.S. Application Data
(63) Continuation of application No. PCT/CN2024/091259, filed on May 6, 2024.

(30) Foreign Application Priority Data
Jul. 27, 2023 (CN) 202310934600.4
Mar. 26, 2024 (CN) 202410355854.5

(51) Int. Cl. H10K 59/82; H10K 59/122; H10K 59/40; H10K 59/88

(52) U.S. Cl. CPC H10K 59/82; H10K 59/122; H10K 59/40; H10K 59/88

(57) ABSTRACT

A display panel with a first display area, and the display panel includes a base plate, light-emitting units, an isolation structure; each of the light-emitting unit includes a first electrode, a light-emitting functional portion, and a second electrode, the second electrodes of adjacent light-emitting units are spaced apart, the light-emitting units include at least one first light-emitting unit; the isolation structure includes a plurality of first isolation structures, the first isolation structure includes a first physical portion and a first opening portion, the first physical portion is arranged around the first opening portion, the first opening portion exposes at least a portion of the first electrode of the first light-emitting unit, the second electrode of the first light-emitting unit is electrically connected with the first isolation structure, and at least a portion of adjacent first isolation structures are electrically connected through the light-transmitting connection portion.

### CROSS REFERENCE TO RELATED APPLICATION

The present application is a continuation application of International Application No. PCT/CN2024/091259, filed on May 6, 2024, which claims priority to Chinese Patent Application No. 202310934600.4 filed on Jul. 27, 2023, and Chinese Patent Application No. 202410355854.5 filed on Mar. 26, 2024, all of which are incorporated herein by reference in their entireties.

### TECHNICAL FIELD

The present application relates to the field of display technology, and particularly to a display panel.

### BACKGROUND

Planar display apparatus based on Organic Light Emitting Diode (OLED) and Light Emitting Diode (LED), etc., are widely used in cell phones, TVs, notebook computers, desktop computers and other consumer electronic products due to their high image quality, power saving, thin body and wide range of applications, and have become the mainstream of the display apparatus.

However, the performance of current OLED display products needs to be improved.

### SUMMARY

Embodiments of the present application provide a display panel, which can improve the performance of the display panel.

Some embodiments of a first aspect of the present application provide a display panel with a first display area, the display panel including: a base plate; a plurality of light-emitting units each including a first electrode, a light-emitting functional portion, and a second electrode stacked along a direction away from the base plate, second electrodes of adjacent light-emitting units being spaced apart, and the plurality of light-emitting units including at least one first light-emitting unit located in the first display area; an isolation structure formed at one side of the base plate and including a plurality of first isolation structures spaced apart within the first display area, the first isolation structure including a first physical portion and a first opening portion, the first physical portion being arranged around the first opening portion, the first opening portion exposing at least a portion of the first electrode of the first light-emitting unit, and the second electrode of the first light-emitting unit being electrically connected with the first isolation structure; and a light-transmitting connection portion, at least a portion of adjacent first isolation structures being electrically connected through the light-transmitting connection portion.

Some embodiments of a second aspect of the present application further provide a display panel with a first display sub-area, the display panel including: a base plate; a plurality of light-emitting units each including a first electrode, a light-emitting functional portion, and a second electrode stacked along a direction away from the base plate, second electrodes of adjacent light-emitting units being spaced apart; an isolation structure formed at one side of the base plate and including a first physical portion and a first opening portion, the first physical portion being arranged around the first opening portion, the first opening portion exposing at least a portion of the first electrode of the light-emitting unit, the isolation structure further including at least one light-transmitting aperture arranged in the first display sub-area; and a first shielding portion located at one side of the base plate, an orthographic projection of the first shielding portion on the base plate overlapping an orthographic projection of the light-transmitting aperture on the base plate, and the first shielding portion having a light-transmitting structure.

The display panel according to the present application includes the base plate, the light-emitting units, and the isolation structure. The light-emitting units include the first light-emitting unit located in the first display area, and the isolation structure includes the first isolation structures located in the first display area. The first isolation structure includes the first physical portion and the first opening portion, the first physical portion is arranged around the first electrode of the first light-emitting unit, and the first opening portion exposes at least a portion of the first electrode of the first light-emitting unit. Adjacent first isolation structures are spaced apart from each other, the second electrodes of adjacent first light-emitting units are spaced apart from each other, the second electrode of the first light-emitting unit is electrically connected with the first isolation structure, and at least a portion of adjacent first isolation structures are electrically connected through the light-transmitting connection portion. On the one hand, at least a portion of the second electrodes within the first display area can be electrically connected. On the other hand, adjacent first isolation structures are spaced apart, so that a spacing area is formed between adjacent first isolation structures, the light-transmitting connection portion with great light-transmitting performance is arranged within the spacing area, and thus the light transmittance of the area between adjacent first isolation structures can be increased, so as to increase the light transmittance of the first display area, which facilitates integrating a photosensitive device under the first display area or achieving transparent display.

### BRIEF DESCRIPTION OF THE DRAWINGS

In order to more clearly illustrate the technical solutions of the embodiments of the present application, the drawings to be used in the embodiments of the present application will be briefly introduced below. For those of ordinary skill in the art, other drawings can be further obtained based on these drawings without inventive effort.

FIG. 1 shows a top view of a display panel according to the embodiments of the present application;

FIG. 2 shows a partially enlarged view of a first display area in FIG. 1;

FIG. 3 shows a sectional view along P-P′ in FIG. 2;

FIG. 4 shows another partially enlarged view of the first display area in FIG. 1;

FIG. 5 shows a partial schematic view of a display panel according to the embodiments of the present application;

FIG. 6 shows another sectional view along P-P′ in FIG. 2;

FIG. 7 shows another sectional view along P-P′ in FIG. 2;

FIG. 8 shows another sectional view along P-P′ in FIG. 2;

FIG. 9 shows another sectional view along P-P′ in FIG. 2;

FIG. 10 shows another sectional view along P-P′ in FIG. 2;

FIG. 11 shows an enlarged view of area M in FIG. 1;

FIG. 12 shows a sectional view along Q-Q′ in FIG. 11;

FIG. 13 shows another enlarged view of area M in FIG. 1;

FIG. 14 shows a sectional view of a display panel according to the embodiments of the present application;

FIG. 15 shows another sectional view of a display panel according to the embodiments of the present application;

FIG. 16 shows an enlarged view of area N in FIG. 1;

FIG. 17 shows a sectional view along E-E′ in FIG. 16;

FIG. 18 shows a sectional view along F-F′ in FIG. 16;

FIG. 19 shows a sectional view along W-W′ in FIG. 13;

FIG. 20 shows another sectional view along W-W′ in FIG. 13;

FIG. 21 shows another sectional view along W-W′ in FIG. 13;

FIG. 22 shows another sectional view along W-W′ in FIG. 13;

FIG. 23 shows another sectional view along W-W′ in FIG. 13;

FIG. 24 shows a sectional view along Y-Y′ in FIG. 13;

FIG. 25 shows a schematic structure diagram of a display apparatus according to the embodiments of the present application.

### REFERENCE NUMERALS

1—display panel; A1—first display area; A3—transition area; A2—second display area; A21—first display sub-area; A22—second display sub-area; B—bezel area; 10—base plate; 11—light-emitting unit; 111—first electrode; 112—light-emitting functional portion; 113—second electrode; 114—first light-emitting unit; 1141—red first light-emitting unit; 1142—green first light-emitting unit; 1143—blue first light-emitting unit; 115—second light-emitting unit; 1151—red second light-emitting unit; 1152—green second light-emitting unit; 1153—blue second light-emitting unit; 116—third light-emitting unit; 12—isolation structure; 120—first isolation structure; 121—first physical portion; 122—first opening portion; 123—first isolation portion; 1231—first electrically insulating layer; 1232—first electrically conductive layer; 124—second isolation portion; 125—third isolation portion; 1251—first layer; 1252—second layer; 1253—first extension portion; 126—fourth isolation portion; 13—light-transmitting connection portion; 131—via; 14—pixel defining layer; 141—pixel defining portion; 142—pixel opening; 15—second isolation structure; 151—second physical portion; 152—second opening portion; 153—light-transmitting aperture; 16—first shielding portion; 17—first electrode wiring; 18—encapsulation layer; 20—electrode wiring; 21—third isolation structure; 22—fourth isolation structure; 221—air hole; 23—second shielding portion; 24—dam; 25—organic encapsulation layer; 26—inorganic encapsulation layer; 2—display apparatus; 154—fifth isolation portion; 1541—second electrically insulating layer; 1542—second electrically conductive layer; 155—sixth isolation portion; 156—seventh isolation portion; 1561—first functional layer; 1562—second functional layer; 1563—second extension portion; 157—eighth isolation portion.

### DETAILED DESCRIPTION

Features and exemplary embodiments of various aspects of the present application will be described in detail below. In order to make the objectives, technical solutions, and advantages of the present application clearer, the present application will be further described in detail below with reference to the drawings and specific embodiments. It should be understood that the specific embodiments described herein are merely intended to explain the present application, rather than to limit the present application. For those skilled in the art, the present application can be implemented without some of these specific details. The following description of the embodiments is merely to provide a better understanding of the present application by illustrating the examples of the present application.

It should be noted that, in the present application, relational terms, such as first and second, are used merely to distinguish one entity or operation from another entity or operation, without necessarily requiring or implying any actual such relationships or orders for these entities or operations. Moreover, the terms “comprise”, “include”, or any other variants thereof, are intended to represent a non-exclusive inclusion, such that a process, method, article or device comprising/including a series of elements includes not only those elements, but also other elements that are not explicitly listed or elements inherent to such a process, method, article or device. Without more constraints, the elements following an expression “comprise/include . . . ” do not exclude the existence of additional identical elements in the process, method, article or device that includes the elements.

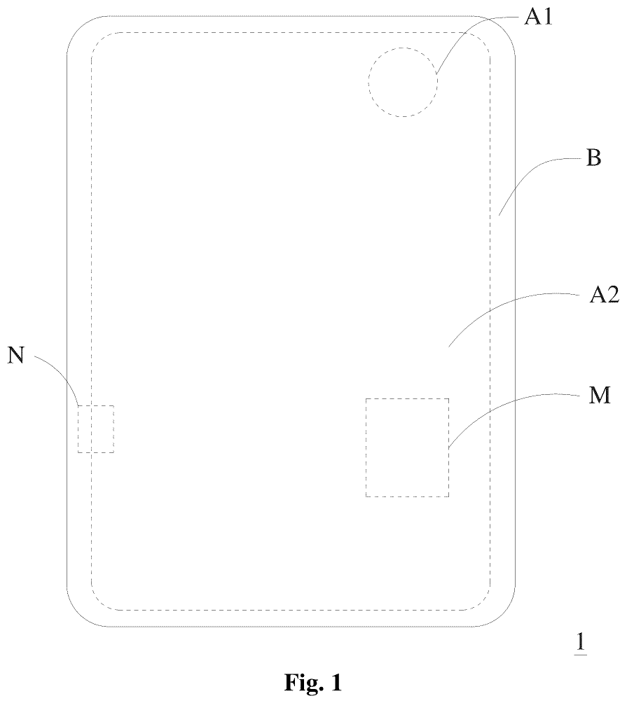

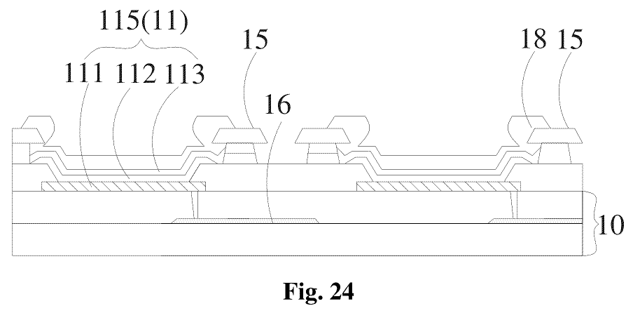

For a better understanding of the present application, a display panel and a display apparatus according to the embodiments of the present application are described in detail below in conjunction with FIGS. 1 to 25.

Referring to FIG. 1, the embodiments of the present application provide a display panel 1 including a first display area A1.

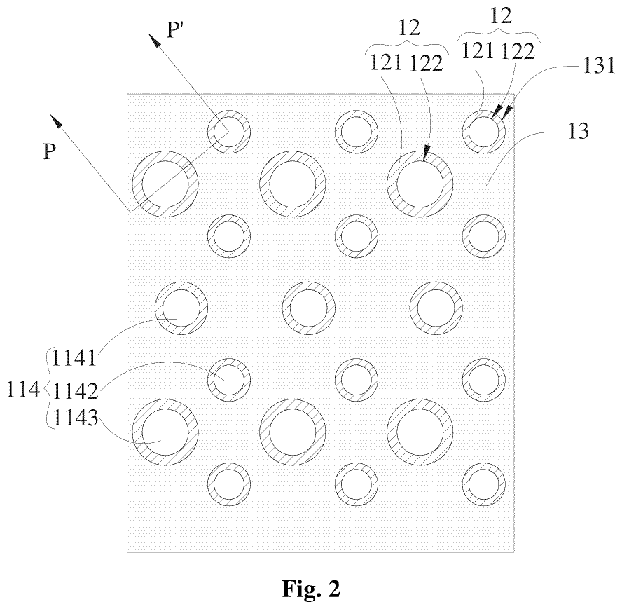

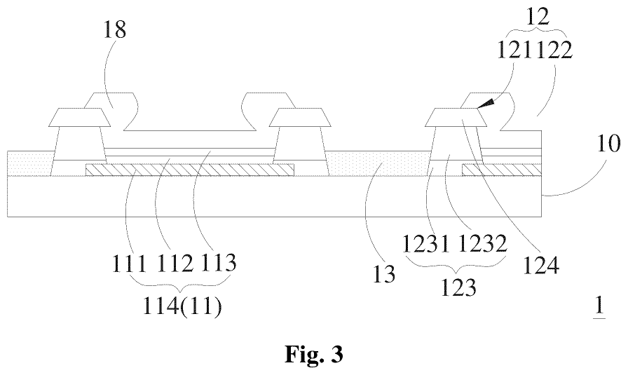

As shown in FIGS. 2 and 3, the display panel 1 according to the present application includes a base plate 10, light-emitting units 11, and an isolation structure 12. The number of the light-emitting units 11 is two or more, each of the light-emitting unit 11 includes a first electrode 111, a light-emitting functional portion 112, and a second electrode 113 stacked along a direction away from the base plate 10, the second electrodes 113 of adjacent light-emitting units 11 are spaced apart, the plurality of light-emitting units 11 include at least one first light-emitting unit 114 located in the first display area A1. The isolation structure 12 is formed at one side of the base plate 10 and includes a plurality of first isolation structures 120 spaced apart within the first display area A1, the first isolation structure 120 includes a first physical portion 121 and a first opening portion 122, the first physical portion 121 is arranged around the first opening portion 122, the first opening portion 122 exposes at least a portion of the first electrode 111 of the first light-emitting unit 114, the second electrode 113 of the first light-emitting unit 114 is electrically connected with the first isolation structure 120, and at least a portion of adjacent first isolation structures 120 are electrically connected through the light-transmitting connection portion 13.

The display panel 1 according to the present application includes the base plate 10, the light-emitting units 11, and the isolation structure 12. The light-emitting units 11 include the first light-emitting unit 114 located in the first display area A1, and the isolation structure 12 includes the first isolation structures 120 located in the first display area A1. The first isolation structure 120 includes the first physical portion 121 and the first opening portion 122, the first physical portion 121 is arranged around the first opening portion, and the first opening portion 122 exposes at least a portion of the first electrode 111 of the first light-emitting unit 114. Adjacent first isolation structures 120 are spaced apart from each other, the second electrodes 113 of adjacent first light-emitting units 114 are spaced apart from each other, the second electrode 113 of the first light-emitting unit 114 is electrically connected with the first isolation structure 120, and at least a portion of adjacent first isolation structures 120 are electrically connected through the light-transmitting connection portion 13. On the one hand, at least a portion of the second electrodes 113 within the first display area A1 can be electrically connected, so as to reduce the number and length of the power supply wires for supplying power to the second electrodes 113 within the first display area A1, which facilitates simplifying wiring. On the other hand, adjacent first isolation structures 120 are spaced apart, so that a spacing area is formed between adjacent first isolation structures 120, the light-transmitting connection portion 13 with great light-transmitting performance is arranged within the spacing area, and thus the light transmittance of the area between adjacent first isolation structures 120 can be increased, so as to increase the light transmittance of the first display area A1, which facilitates integrating a photosensitive device under the first display area A1 or achieving transparent display.

Specifically, the first isolation structures 120 may be in one-to-one correspondence with the first light-emitting units 114, which is not limited herein.

In a possible implementation, the light-transmitting connection portion 13 may include a transparent electrically conductive material such as indium tin oxide or indium zinc oxide, which is not specifically limited herein.

In a possible implementation, as shown in FIG. 2, the light-transmitting connection portion 13 has a mesh structure continuously arranged as a whole layer and includes a via 131 opposite to the first opening portion 122.

In the above implementation, the light-transmitting connection portion 13 is continuously arranged as a whole layer and patterned to form the via 131 opposite to the first opening portion 122, thereby exposing the first light-emitting unit 114. The light-transmitting connection portion 13 has a mesh structure continuously arranged as a whole layer, and thus can have a larger area and reduced electrical resistance, so as to reduce the power consumption of the display panel 1. Moreover, since the light-transmitting connection portion 13 covers the area between adjacent first isolation structures 120, the effect of the patterning of the light-transmitting connection portion 13 on the optical performance of the photosensitive device integrated under the first display area A1 can be reduced, and the probability of diffraction of the light passing through the light-transmitting connection portion 13 can be reduced, so as to reduce the undesirable effect of diffraction on the photosensitive device.

In addition, the light-transmitting connection portion 13 having a mesh structure continuously arranged as a whole layer can effectively reduce signal interference between the base plate 10 and a film layer of the first isolation structure 120 at a side away from the base plate 10. Specifically, the display panel 1 may further include a touch control layer located at a side of the isolation structure away from the base plate 10, and the light-transmitting connection portion 13 is located between the base plate 10 and the touch control layer. The touch control layer includes a touch control electrode, and the base plate 10 is provided with a signal line, such as a data signal line, for driving the first light-emitting unit to display. The touch control electrode and the signal line within the base plate 10 may interfere with each other. By arranging the light-transmitting connection portion 13 having a mesh structure between the touch control layer and the base plate 10, the interference between the touch control electrode and the signal line within the base plate 10 can be reduced by the shielding effect of the light-transmitting connection portion 13 having a mesh structure, and thus the performance of the display panel 1 can be improved.

In the above implementation, the orthographic projection of the via 131 on the base plate 10 may be arranged to be larger than the orthographic projection of the first opening portion 122 on the base plate 10 for better bypassing the first light-emitting unit 114.

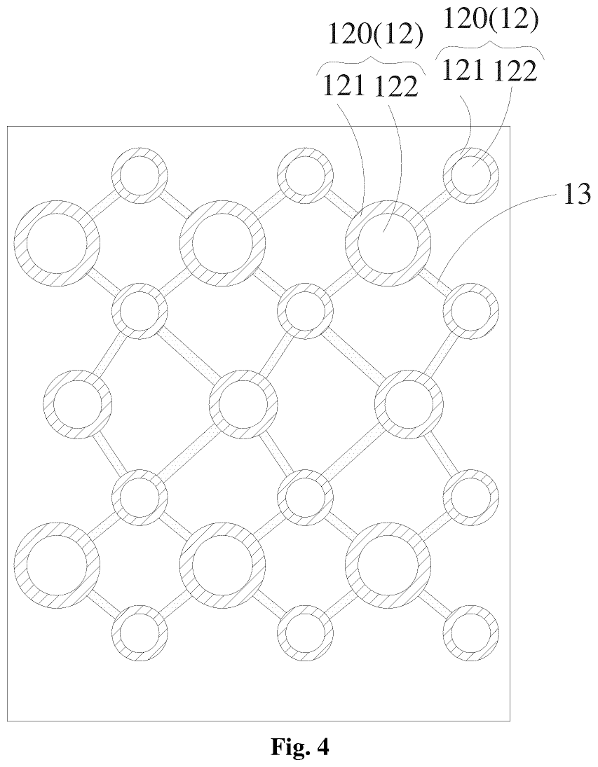

In a possible implementation, as shown in FIG. 4, the light-transmitting connection portion 13 is in the form of a strip and arranged between two adjacent first isolation structures 120, one end of the light-transmitting connection portion 13 is electrically connected with one of the first isolation structures 120, and the other end of the light-transmitting connection portion 13 is electrically connected with the other of the first isolation structures 120.

In the above implementation, the light-transmitting connection portion 13 being in the form of a strip may further reduce the effect of the light-transmitting connection portion 13 on the light transmittance of the area between the first isolation structures 120, thereby further increasing the light transmittance of the first display area A1.

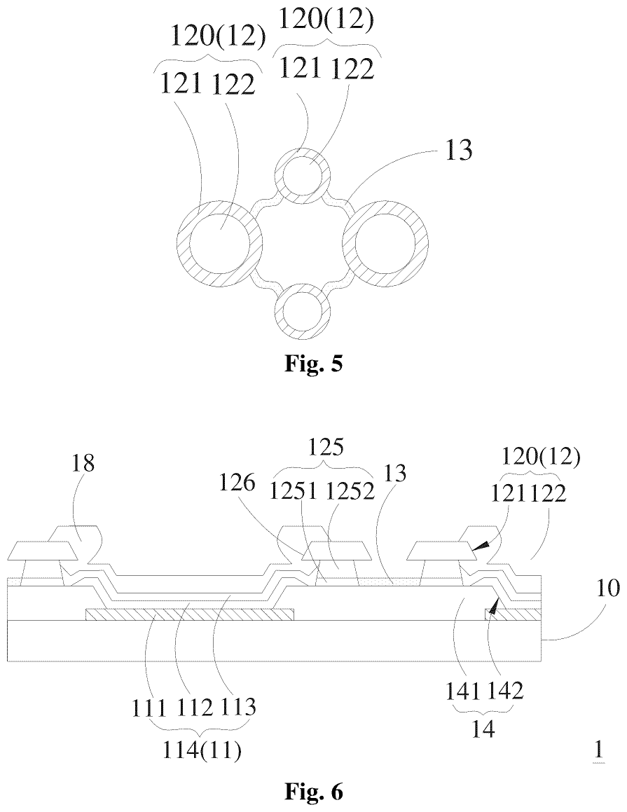

In a possible implementation, as shown in FIG. 4, the orthographic projection of the light-transmitting connection portion 13 on the base plate 10 extends along a straight line, or as shown in FIG. 5, the orthographic projection of the light-transmitting connection portion 13 on the base plate 10 extends along a curve.

In the above implementation, the orthographic projection of the light-transmitting connection portion 13 on the base plate 10 extends along a straight line, and thus the total length of the light-transmitting connection portion 13 can be less, thereby further reducing the effect on the light transmittance of the area between the first isolation structures 120. Moreover, the orthographic projection of the light-transmitting connection portion 13 on the base plate 10 extending along a straight line can reduce the difficulty of preparing the light-transmitting connection portion 13, so as to reduce the preparation cost.

In the above implementation, the orthographic projection of the light-transmitting connection portion 13 on the base plate 10 extends along a curve, and thus the probability of diffraction of light due to the shape of the light-transmitting connection portion 13 can be reduced, thereby reducing the effect of the patterning of the light-transmitting connection portion 13 on the optical performance of the photosensitive device integrated under the first display area A1.

In a possible implementation, as shown in FIG. 3, the first isolation structure 120 includes a first isolation portion 123 including a first electrically insulating layer 1231 and a first electrically conductive layer 1232, the first electrically insulating layer 1231 covers at least an edge of the first electrode 111 of the first light-emitting unit 114, the first electrically conductive layer 1232 is located at a side of the first electrically insulating layer 1231 away from the base plate 10, and the second electrode 113 of the first light-emitting unit 114 and the light-transmitting connection portion 13 are electrically connected with the first electrically conductive layer 1232.

In the above implementation, the pixel defining layer 14 in the display panel 1 is omitted, while the isolation structure 12 is used to define the light-emitting unit 11. The isolation structure 12 includes the first isolation structure 120, the first isolation structure 120 includes the first isolation portion 123, the first isolation portion 123 includes the first electrically insulating layer 1231 and the first electrically conductive layer 1232, and the first electrically conductive layer 1232 is located at a side of the first electrically insulating layer 1231 away from the base plate 10. Herein, the first electrically insulating layer 1231 is in direct contact with the base plate 10 and the side of the first electrode 111 of the first light-emitting unit 114 away from the base plate 10, and the first electrically insulating layer 1231 covers the edge of the first electrode 111 of the first light-emitting unit 114, so as to achieve mutual electrical insulation for the first electrodes 111 of adjacent first light-emitting units 114 and protect the first electrodes 111 of the first light-emitting units 114. The first electrically conductive layer 1232 and the light-transmitting connection portion 13 are used to connect the second electrodes 113 of different first light-emitting units 114. Specifically, the second electrode 113 of the first light-emitting unit 114 is in direct contact with the sidewall of the first electrically conductive layer 1232 to achieve the electrical connection between the second electrode 113 of the first light-emitting unit 114 and the first isolation structure 120, and adjacent first isolation structures 120 are electrically connected through the light-transmitting connection portion 13, thereby realizing the electrical connection between the second electrodes 113 of different first light-emitting units 114.

In a possible implementation, as shown in FIG. 3, the first isolation structure 120 further includes a second isolation portion 124 located at a side of the first isolation portion 123 away from the base plate 10, and an orthographic projection of the first isolation portion 123 on the base plate 10 is located within an orthographic projection of the second isolation portion 124 on the base plate 10.

In the above implementation, the first isolation structure 120 includes the first isolation portion 123 and the second isolation portion 124 that are stacked along a direction away from the base plate, and the orthographic projection of the first isolation portion 123 on the base plate 10 is located within the orthographic projection of the second isolation portion 124 on the base plate 10. Therefore, when preparing the first light-emitting units 114 of various colors, the individual film layers in the first light-emitting units 114 of one color may be formed first as a whole layer, then the first light-emitting units 114 of that color may be formed by etching at the designated first opening portions 122, and the first opening portions 122 for forming the first light-emitting units 114 of other colors are exposed. The first light-emitting units 114 of different colors may be prepared in sequence, while no mask plate is needed in the above preparation process, and further the pixel defining layer 14 and support column located at a side of the pixel defining layer 14 away from the base plate 10 for supporting a mask plate are not needed, and thus the preparation cost can be saved. The first isolation structure 120 may be formed using a dark-colored material, so as to provide light-shading effect and prevent optical crosstalk between adjacent first light-emitting units 114.

In a possible implementation, the first isolation structure 120 has an annular structure arranged around at least one first light-emitting unit 114. Therefore, the first light-emitting unit 114 can be defined and adjacent first isolation structures 120 can be spaced apart, thereby increasing the light transmittance between adjacent first isolation structures 120.

In a possible implementation, as shown in FIG. 6, the display panel 1 further includes a pixel defining layer 14 located between the first electrode 111 and the isolation structure 12, the pixel defining layer 14 includes a pixel defining portion 141 and a pixel opening 142, and the pixel openings 142 and the first opening portions 122 are arranged in one-to-one correspondence and connected respectively for accommodating the light-emitting units 11. The first isolation structure 120 includes a third isolation portion 125 including an electrically conductive material, and the light-transmitting connection portion 13 and the second electrode of the first light-emitting unit are connected with the third isolation portion 125.

In the above implementation, the display panel 1 includes the pixel defining layer 14 and the isolation structure 12 located at a side of the pixel defining layer 14 away from the base plate 10. The pixel-defining layer 14 is used to define the light-emitting unit 11. The first isolation structure 120 includes the third isolation portion 125 in direct contact with a side surface of the pixel defining layer 14 away from the base plate 10, the third isolation portion 125 includes an electrically conductive material, and the second electrode 113 of the first light-emitting unit 114 and the light-transmitting connection portion 13 are connected with the third isolation portion 125, so as to achieve the electrical connection for the second electrodes 113 of different first light-emitting units 114.

In a possible implementation, as shown in FIG. 6, the third isolation portion 125 includes a first layer 1251 and a second layer 1252 located at a side of the first layer 1251 away from the base plate 10, the first layer 1251 includes an electrically conductive material, and the light-transmitting connection portion 13 and the second electrode of the first light-emitting unit 114 are connected with the first layer 1251.

In the above implementation, the material of the first layer 1251 may be a metal, such as molybdenum, and the material of the second layer 1252 may be a metal, such as aluminum. The first layer 1251 may protect the second layer 1252 and prevent oxidation of the second layer 1252 due to water and oxygen from the side corresponding to the base plate 10.

In the above implementation, the first isolation structure 120 may further include a fourth isolation portion 126, and an orthographic projection of the third isolation portion 125 on the base plate 10 is located within an orthographic projection of the fourth isolation portion 126 on the base plate 10.

In the above implementation, the first isolation structure 120 includes the third isolation portion 125 and the fourth isolation portion 126, and the orthographic projection of the third isolation portion 125 on the base plate 10 is located within the orthographic projection of the fourth isolation portion 126 on the base plate 10. Therefore, when preparing the first light-emitting units 114 of various colors, the individual film layers in the first light-emitting units 114 of one color may be formed first as a whole layer, then the first light-emitting units 114 of that color may be formed by etching at the designated first opening portions 122, and the first opening portions 122 for forming the first light-emitting units 114 of other colors are exposed. The first light-emitting units 114 of different colors may be prepared in sequence, while no mask plate is needed in the above preparation process, and further the pixel defining layer 14 and support column located at a side of the pixel defining layer 14 away from the base plate 10 for supporting a mask plate are not needed, and thus the preparation cost can be saved. The first isolation structure 120 may be formed using a dark-colored material, so as to provide light-shading effect and prevent optical crosstalk between adjacent first light-emitting units 114.

In a possible implementation, as shown in FIG. 6, the light-transmitting connection portion 13 and the first layer 1251 are distributed along a direction parallel to a plane where the base plate 10 is located and are in contact with each other. The orthographic projection of the second layer 1252 on the base plate 10 covers a portion of the orthographic projection of the light-transmitting connection portion 13 on the base plate 10, or the orthographic projection of the second layer 1252 on the base plate 10 is spaced apart from the orthographic projection of the light-transmitting connection portion 13 on the base plate 10.

In the above implementation, the light-transmitting connection portion 13 and a sidewall of the first layer 1251 are in contact, and thus the light-transmitting connection portion 13 and the first layer 1251 are electrically connected. A portion of the light-transmitting connection portion 13 is located between the second layer 1252 and the pixel defining layer 14, i.e., the orthographic projection of the second layer 1252 on the base plate 10 covers a portion of the orthographic projection of the light-transmitting connection portion 13 on the base plate 10, so as to protect the contact portion between the first layer 1251 and the light-transmitting connection portion 13 by the second layer 1252, and reduce the effect of the subsequent process on the contact portion. Moreover, if the material of the second layer 1252 is a metal, the contact resistance between the light-transmitting connection portion 13 and the first layer 1251 can be further reduced.

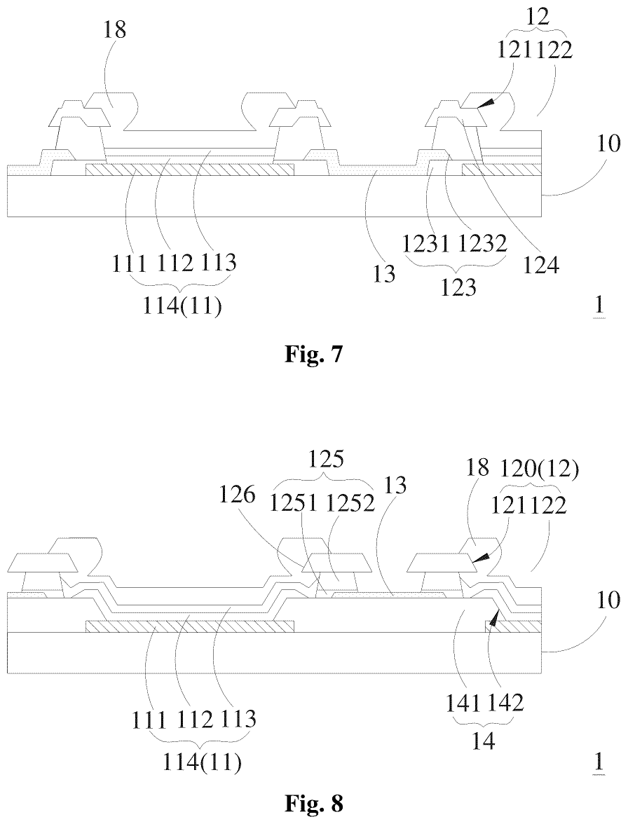

In a possible implementation, as shown in FIG. 7, a portion of the light-transmitting connection portion 13 is located at a side of the first layer 1251 away from the base plate 10 and covers the edge of the first layer 1251, and the orthographic projection of the second layer 1252 on the base plate 10 covers a portion of the orthographic projection of the light-transmitting connection portion 13 on the base plate 10. Therefore, the light-transmitting connection portion 13 and the first layer 1251 can be electrically connected. Moreover, the contact portion between the first layer 1251 and the light-transmitting connection portion 13 can be protected by the second layer 1252. In another possible implementation, as shown in FIG. 8, the light-transmitting connection portion 13 is in contact with a side of the pixel defining layer 14 away from the base plate 10, and the first layer 1251 covers the edge of the light-transmitting connection portion 13.

In the above implementation, the light-transmitting connection portion 13 is formed at a side of the pixel defining layer 14 away from the base plate 10, and the first layer 1251 is formed at a side of the light-transmitting connection portion 13 away from the base plate 10, i.e., the light-transmitting connection portion 13 is prepared first, followed by the first layer 1251. The first layer 1251 covers the edge of the light-transmitting connection portion 13, i.e., the first layer 1251 is in contact with a sidewall of the light-transmitting connection portion 13 at a side towards the first opening portion 122. Moreover, the first layer 1251 is in contact with a side surface of the light-transmitting connection portion 13 away from the base plate 10, which can increase the contact area between the first layer 1251 and the light-transmitting connection portion 13, so as to improve the connection stability and reduce the contact resistance between the first layer 1251 and the light-transmitting connection portion 13.

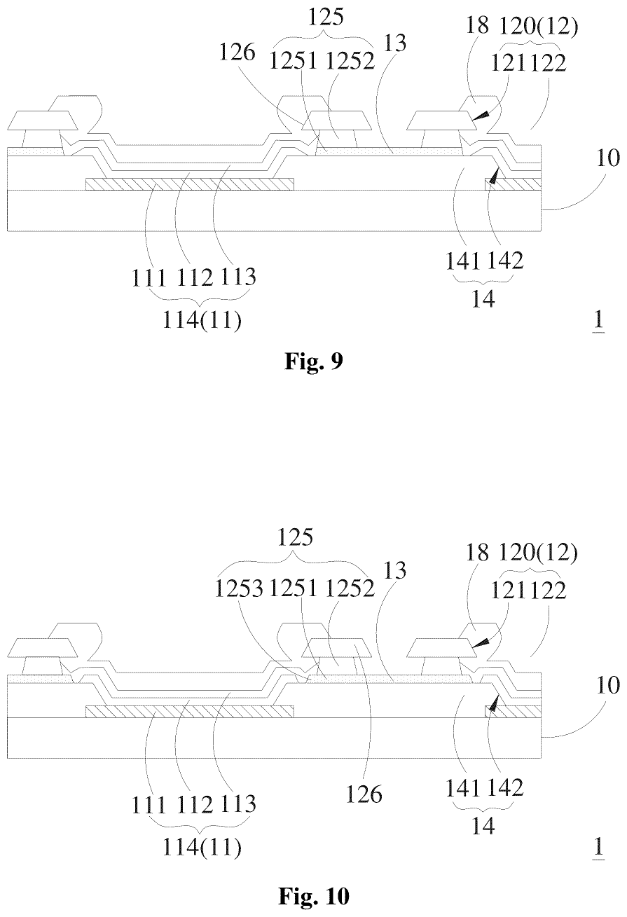

In another possible implementation, as shown in FIG. 9, the light-transmitting connection portion 13 and the first layer 1251 are of a same material and form a one-piece structure.

In the above implementation, the light-transmitting connection portion 13 and the first layer 1251 are prepared in a same process and form a one-piece structure, and thus the connection stability between the light-transmitting connection portion 13 and the first layer 1251 is stronger, and the preparation process can be saved, thereby reducing the preparation cost. In such cases, the material of the first layer 1251 is the same as the material of the light-transmitting connection portion 13, both of which are transparent electrically conductive materials.

In the above implementation, as shown in FIG. 10, one end of the first layer 1251 close to the first opening portion 122 includes a first extension portion 1253 extending beyond the second layer 1252, an orthographic projection of the first extension portion 1253 on the base plate 10 is spaced apart from the orthographic projection of the second layer 1252 on the base plate 10, and the orthographic projection of the first extension portion 1253 on the base plate 10 is located within an orthographic projection of the fourth isolation portion 126 on the base plate 10.

In the above implementation, with the first extension portion 1253 of the first layer 1251, a preset distance is between an end of the second layer 1252 close to the first opening portion 122 and an end of the first layer 1251 close to the first opening portion 122, the contact area between the second electrode 113 of the first light-emitting unit 114 and the first layer 1251 can be further increased, thereby improving the stability of electrical connection between the second electrode 113 of the first light-emitting unit 114 and the first isolation structure 120, and also reducing contact resistance.

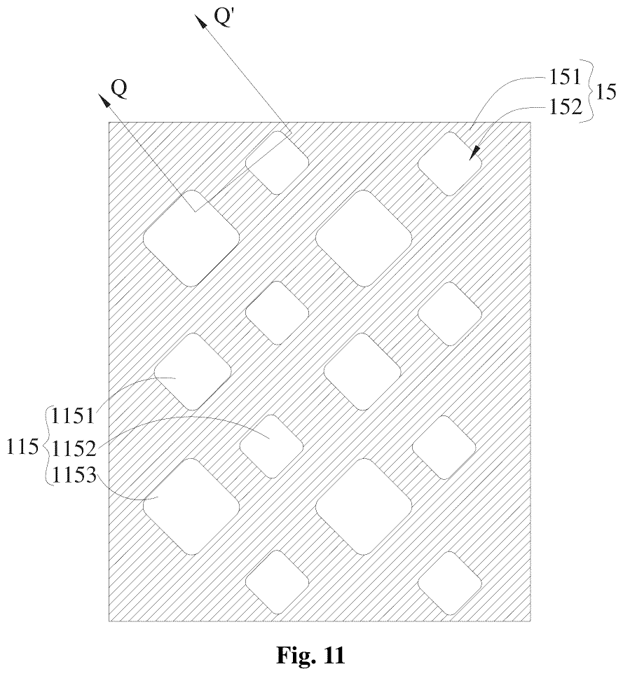

In a possible implementation, as shown in FIGS. 11 and 2, the display panel 1 further includes a second display area A2, i.e., the display panel includes the first display area A1 and the second display area A2, and the second display area A2 surrounds at least a portion of the first display area A1.

The display panel 1 according to the present application includes the first display area A1 and the second display area A2, and the light transmittance of the second display area A2 may be set to be less than the light transmittance of the first display area A1, so as to facilitate integrating a photosensitive device, such as a camera module, under the first display area A1. Alternatively, the light transmittance of the first display area A1 may be the same as the light transmittance of the second display area A2 for achieving transparent display, which is not limited herein.

In the display panel according to the present application, the light-emitting units 11 further include a second light-emitting unit 115 located in the second display area A2, the orthographic projection of the first light-emitting unit 114 on the base plate 10 is smaller than the orthographic projection of the second light-emitting unit 115 of a same color on the base plate 10, and a spacing between adjacent first light-emitting units 114 is greater than a spacing between adjacent second light-emitting units 115.

Specifically, the display panel 1 may include the light-emitting units 11 of at least three colors. Herein, the light-emitting units 11 may include the first light-emitting units 114 of at least three colors, such as red first light-emitting units 1141, green first light-emitting units 1142, and blue first light-emitting units 1143. Moreover, the light-emitting units 11 may include the second light-emitting units 115 of at least three colors, such as red second light-emitting units 1151, green second light-emitting units 1152, and blue second light-emitting units 1153.

Specifically, the arrangement of the first light-emitting units 114 within the first display area A1 may be the same as or different from the arrangement of the second light-emitting units 115 within the second display area A2, which is not limited herein.

Specifically, the orthographic projection of the first light-emitting unit 114 on the base plate 10 is smaller than the orthographic projection of the second light-emitting unit 115 of a same color on the base plate 10, so that the light transmittance of the first display area A1 can be increased to facilitate integrating a photosensitive device under the first display area A1 or achieving transparent display.

Specifically, the spacing between adjacent first light-emitting units 114 is greater than the spacing between adjacent second light-emitting units 115. Herein, the spacing between any two adjacent first light-emitting units 114 may be greater than the spacing between any two adjacent second light-emitting units 115, or the spacing between any two adjacent first light-emitting units 114 of a first color may be greater than the spacing between any two adjacent second light-emitting units 115 of the first color, and the first color may be red, green, or blue, which is not limited herein. The above arrangement can reduce the ratio of the total area of all the first light-emitting units 114 within the first display area A1 to the total area of the first display area A1, so as to further increase the light transmittance of the first display area A1.

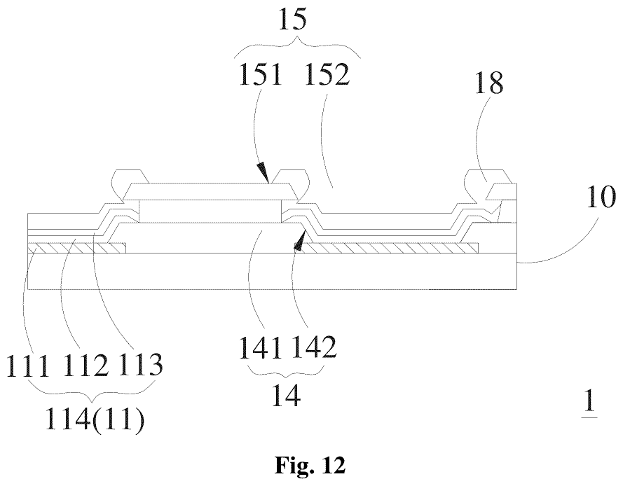

In a possible implementation, as shown in FIGS. 11 and 12, the isolation structure 12 further includes a second isolation structure 15 located within the second display area A2, the second isolation structure 15 is located at a side of the first electrode 111 of the second light-emitting unit 115 away from the base plate 10, the second isolation structure 15 has a mesh structure and includes a second physical portion 151 and a second opening portion 152, the second physical portion 151 is continuously arranged as a whole layer, and the second opening portion 152 is for exposing at least a portion of the first electrode 111 of the second light-emitting unit 115.

In the above implementation, the second isolation structure 15 and the first isolation structure 120 are prepared in the same layer, i.e., prepared as a whole layer in the preparation process, and then the first display area A1 and the second display area A2 are patterned, respectively, to form the first isolation structure 120 in the first display area A1 and the second isolation structure 15 in the second display area A2. Herein, the second isolation structure 15 has the same function as the first isolation structure 120, both of which can make a mask plate to be omitted during the preparation of the light-emitting units 11, improve the preparation process of the light-emitting units 11, and reduce crosstalk between adjacent light-emitting units 11.

Specifically, the second isolation structure 15 and the first isolation structure 120 have the same number of film layers and the same material, which is not be repeated herein.

In the above implementation, within the second display area A2, the second electrode 113 of the second light-emitting unit 115 is electrically connected with the second physical portion 151, so that the second electrodes 113 of the second light-emitting units 115 that are spaced apart can be electrically connected through the second physical portion 151, so as to reduce the number of power supply wires and simplify wiring.

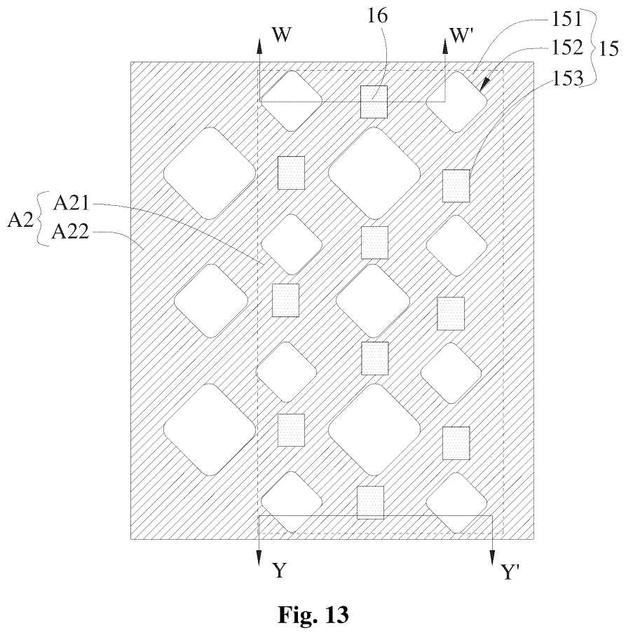

In a possible implementation, as shown in FIG. 13, the second isolation structure 15 further includes a light-transmitting aperture 153 located between adjacent second opening portions 152.

Herein, the light-transmitting aperture 153 may be arranged on the second isolation structure 15 in a portion of the second display area A2, or the light-transmitting aperture 153 may be arranged on the second isolation structure 15 all over the second display area A2. The density of the light-transmitting apertures 153 in various areas within the second display area A2 may be the same or different and may be set according to the demand.

In the above implementation, the light transmittance of the second display area A2 can be increased by arranging the light-transmitting aperture 153 at the portion between adjacent second opening portions 152 in the second isolation structure 15, while the second physical portion 151 in the second isolation structure 15 keeps to be continuously arranged as a whole layer, so as to achieve the electrical connection for different second electrodes 113.

In a possible implementation, the second display area A2 includes a first display sub-area A21 and a second display sub-area A22, the light transmittance of the first display area A1 is greater than a light transmittance of the first display sub-area A21, the light transmittance of the first display sub-area A21 is greater than a light transmittance of the second display sub-area A22, the light-transmitting aperture 153 is arranged on the second isolation structure 15 within the first display sub-area A21.

In the above implementation, when at least one of a fingerprint identification module (FOD), a light sensor, or a distance measuring sensor is integrated under the display panel 1, the light-transmitting aperture 153 is formed in the area between adjacent second light-emitting units 115 in the second isolation structure 15 for transmitting light, so as to achieve fingerprint identification, ambient light intensity detection, and distance measuring. Herein, the first display sub-area A21 is the area for arranging the light-transmitting holes 153, and the first display sub-area A21 is located between adjacent second light-emitting units 115.

In the above implementation, the orthographic projection of the light-transmitting aperture 153 on the base plate 10 may be in the shape of any of a quadrilateral, a circle, or an ellipse, which is not limited herein.

In a possible implementation, as shown in FIG. 13, the display panel further includes a first shielding portion 16 arranged at one side of the base plate 10, an orthographic projection of the first shielding portion 16 on the base plate 10 covers the orthographic projection of the light-transmitting aperture 153 on the base plate 10, the first shielding portion 16 has a light-transmitting structure.

In the above implementation, the first shielding portions 16 and the light-transmitting apertures 153 are in one-to-one correspondence, and the orthographic projection of the first shielding portion 16 on the base plate 10 covers the orthographic projection of the light-transmitting aperture 153 on the base plate 10. Specifically, the first shielding portion 16 may be formed between the second isolation structure 15 and the base plate 10 and is in contact with the second isolation structure 15. The first shielding portion 16 can effectively reduce signal interference between the base plate 10 and a film layer of the second isolation structure at a side away from the base plate 10. Specifically, the display panel 1 may include a touch control layer located at a side of the second isolation structure 15 away from the base plate 10, the touch control layer includes a touch control electrode, and the base plate 10 is provided with a signal wiring for driving the first light-emitting unit 11 to display. Mutual interference between the touch control electrode and the signal wiring within the base plate 10 at the light-transmitting aperture 153 can be reduced by arranging the first shielding portion 16 at the light-transmitting aperture 153, thereby improving the performance of the display panel 1. Specifically, the second isolation structure 15 includes a metal layer, which may shield positions other than the light-transmitting aperture 153, so as to reduce mutual interference between a touch control signal and a display signal.

Specifically, the first shielding portion 16 is electrically connected with the isolation structure 12.

Specifically, the number of the first shielding portions 16 is two or more, the number of the light-transmitting apertures 153 is two or more, and the plurality of first shielding portions 16 and the plurality of light-transmitting apertures 153 are arranged in one-to-one correspondence.

In a possible implementation, the first shielding portion 16 is arranged in the same layer as the light-transmitting connection portion 13. That is, the first shielding portion 16 and the light-transmitting connection portion 13 are both formed using a transparent electrically conductive material, the first shielding portion 16 and the light-transmitting connection portion 13 may be prepared as a whole layer and then patterned, respectively, within the first display area A1 and the second display area A2, so as to form the first shielding portion 16 and the light-transmitting connection portion 13. The first shielding portion 16 being arranged in the same layer as the light-transmitting connection portion 13 can simplify the preparation process.

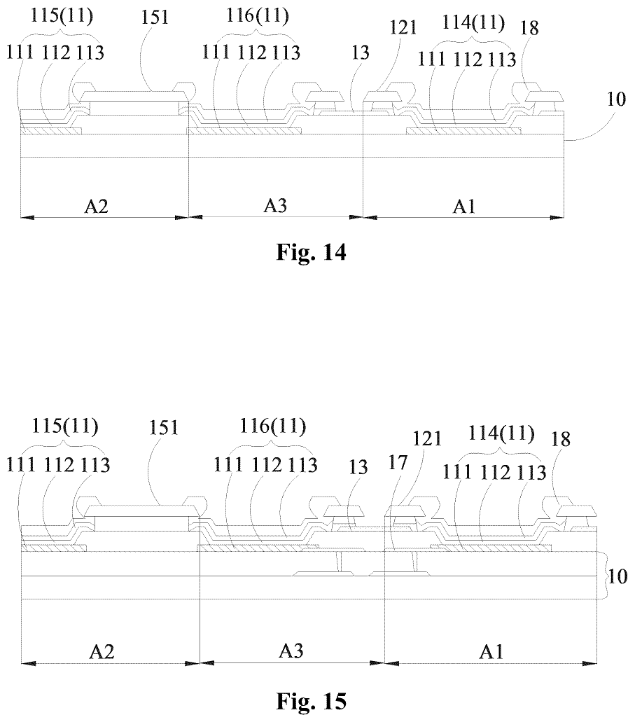

In a possible implementation, as shown in FIG. 14, the second electrode 113 of the first light-emitting unit 114 is electrically connected with the second electrode 113 of the second light-emitting unit 115 through the light-transmitting connection portion 13.

That is, in the above implementation, the second electrodes 113 within the first display area A1 may be electrically connected through the first isolation structures 120 and the light-transmitting connection portion 13, the second electrodes 113 within the second display area A2 may be electrically connected through the second isolation structure 15, and thus the second electrodes 113 all over the display panel 1 (including the first display area A1 and the second display area A2) can be electrically connected by electrically connecting the light-transmitting connection portion 13 with the second isolation structure 15, so as to facilitate centralized power supply to the second electrodes 113 all over the display panel 1, thereby simplifying wiring.

Specifically, at the adjacent position between the first display area A1 and the second display area A2, the first physical portion 121 of the first isolation structure 120 is electrically connected with the second physical portion 151 of the second isolation structure 15 through the light-transmitting connection portion 13, so that the second electrodes 113 within the display panel 1 are electrically connected.

In a possible implementation, the base plate 10 includes a first drive circuit located in the first display area A1, and the first electrode 111 of the first light-emitting unit 114 is connected with the first drive circuit through a first electrode wiring 17; the first electrode wiring 17 includes a transparent electrically conductive material. The first electrode wiring 17 is made of a transparent electrically conductive material, so that the light transmittance of the first display area A1 can be increased.

In a possible implementation, the display panel 1 further includes a transition area A3 located between the first display area A1 and the second display area A2, the light-emitting units 11 includes a third light-emitting unit 116 located in the transition area A3, the base plate 10 includes a second drive circuit located in the transition area A3, the first electrode 111 of the third light-emitting unit 116 is connected with the second driving circuit through a second electrode wiring, and the first electrode 111 of the first light-emitting unit 114 is connected with the second drive circuit through the second electrode wiring.

In the above implementation, by arranging the transition area A3 and electrically connecting both the third light-emitting unit 116 located in the transition area A3 and the first light-emitting unit 114 located in the first display area A1 with the second drive circuit located in the transition area A3, the first drive circuit can be omitted in the first display area A1, and thus the light transmittance of the first display area A1 can be further increased.

Specifically, the second electrode wiring includes a transparent electrically conductive material to further increase the light transmittance of the first display area A1 and the transition area A3.

In a possible implementation, the isolation structure 12 further includes a third isolation structure 21 located in the transition area A3, the second electrode 113 of the third light-emitting unit 116 is connected with the third isolation structure 21.

Specifically, the third isolation structure 21 and the second isolation structure 15 are arranged continuously, and the third isolation structure 21 is electrically connected with the first isolation structure 120 through the light-transmitting connection portion 13; or the third isolation structure 21 has the same structure as the first isolation structure 120, and the third isolation structure 21 is electrically connected with the second isolation structure 15 through the light-transmitting connection portion 13.

The third isolation structure 21 is arranged in the transition area A3, so that when preparing the third light-emitting unit 116, the individual film layers in the third light-emitting units 116 of one color may be formed first as a whole layer, then the third light-emitting units 116 of that color may be formed by etching at the designated positions, and the positions for forming the third light-emitting units 116 of other colors are exposed. The third light-emitting units 116 of different colors may be prepared in sequence, while no mask plate is needed in the above preparation process, and further the pixel defining layer 14 and support column located at a side of the pixel defining layer 14 away from the base plate 10 for supporting a mask plate are not needed, and thus the preparation cost can be saved. The third isolation structure may be formed using a dark-colored material, so as to provide light-shading effect and prevent optical crosstalk between adjacent third light-emitting units 116. The third isolation structure may have the same structure as the first isolation structure or the second isolation structure, which is not limited herein. If the third isolation structure 21 has the same structure as one of the first isolation structure 120 and the second isolation structure 15, the third isolation structure 21 is electrically connected with the other one of the first isolation structure 120 and the second isolation structure 15 through the light-transmitting connection portion 13.

The display panel 1 further includes a third drive circuit located within the second display area A2 for driving the second light-emitting unit 115 to emit light, and the second light-emitting unit 115 is electrically connected with the third drive circuit through an electrode wiring. In a possible implementation, the orthographic projection of the first light-emitting unit 114 on the base plate 10 is in the shape of at least one of an ellipse, a circle, a polygon, or a rounded polygon.

Specifically, if the orthographic projection of the first light-emitting unit 114 on the base plate 10 is in the shape of a circle or an ellipse, the diffraction of light within the first display area A1 can be reduced. If the first light-emitting unit 114 needs to be designed as a rectangle according to display requirements, the corners of the rectangle may be chamfered to form a rounded rectangle, so as to reduce the diffraction of light due to the straight edges.

The display panel according to the present application further includes an encapsulation layer 18, as shown in FIGS. 14 and 15, formed at a side of the light-emitting unit away from the base plate, the encapsulation layers 18 and the light-emitting units are in one-to-one correspondence, and the adjacent encapsulation layers 18 are spaced apart.

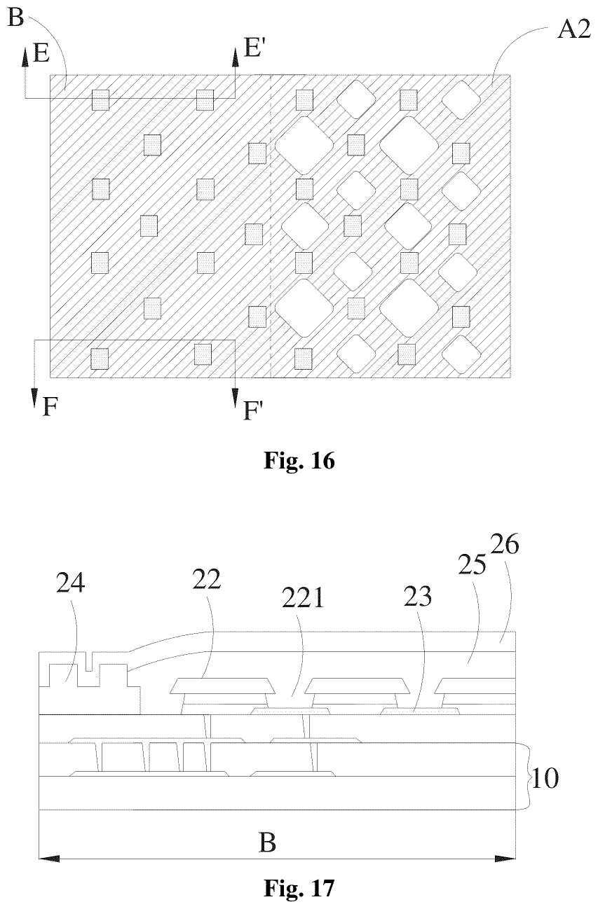

In a possible implementation, as shown in FIGS. 1 and 16, the display panel 1 further includes a bezel area B, the isolation structure 12 further includes a fourth isolation structure 22 located within the bezel area B, the fourth isolation structure 22 and the second isolation structure 15 are arranged continuously, and the fourth isolation structure 22 includes an air hole 221.

In the above implementation, in the bezel area B of the display panel 1, the isolation structure 12 includes the fourth isolation structure 22 located in the bezel area B of the display panel 1, and the fourth isolation structure 22 and the second isolation structure 15 are integrally arranged, so as to simplify the preparation process. The fourth isolation structure 22 includes the air hole 221, and thus the air permeability between the fourth isolation structure 22 and the underlying contact film layer can be improved to avoid the protuberance of the fourth isolation structure 22 due to poor air permeability, so as to reduce the separation between the fourth isolation structure 22 and the underlying film layer, thereby facilitating increasing the product yield rate.

Specifically, the air hole 221 is arranged in the same manner as the light-transmitting aperture 153.

The fourth isolation structure 22 includes the air hole 221 arranged in the same manner as the light-transmitting aperture 153 in the second isolation structure 15, and the light-transmitting aperture 153 and the air hole 221 are prepared in a same process, so that the fourth isolation structure 22 and the second isolation structure 15 are prepared in a same process, which facilitates simplifying the preparation process.

Specifically, the bezel area includes a second shielding portion 23, the second shielding portion 23 is arranged at one side of the base plate 10, and an orthographic projection of the second shielding portion 23 on the base plate 10 covers an orthographic projection of the air hole 221 on the base plate 10.

In the above implementation, in order to ensure the shielding effect of the bezel area B and reduce the mutual interference between a signal within the touch control layer and a signal within the base plate 10 at the air hole 221, the second shielding portion 23 is formed at a position opposite to the air hole 221 for shielding the signals, so as to reduce the mutual interference between the signal within the touch control layer and the signal within the base plate 10.

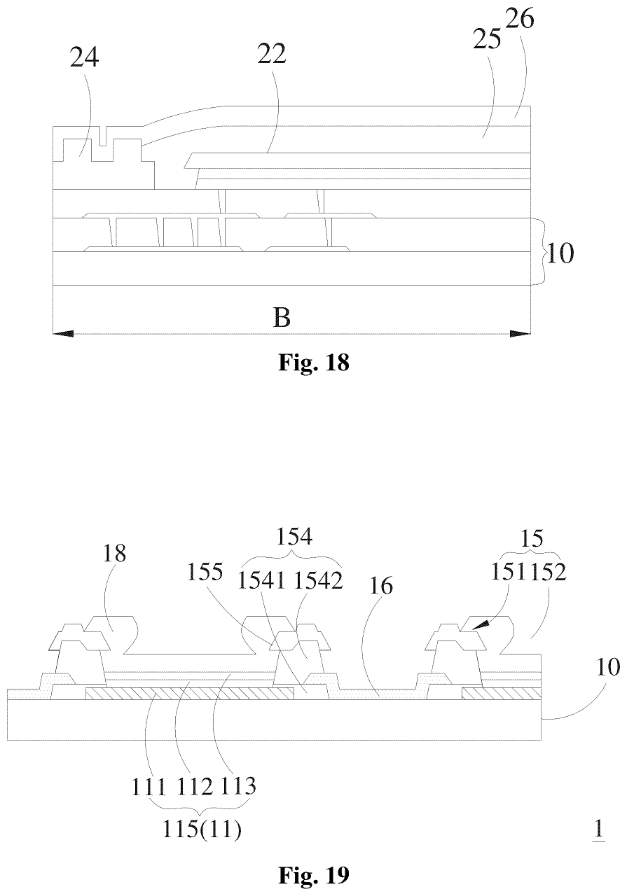

In a possible implementation, as shown in FIGS. 17 and 18, the second shielding portion 23 is arranged in the same layer as the first shielding portion 16. That is, the second shielding portion 23 and the first shielding portion 16 are prepared in a same process, thereby simplifying the preparation process and reducing the preparation cost.

In a possible implementation, as shown in FIGS. 17 and 18, the second shielding portions 23 and the air holes 221 are arranged in one-to-one correspondence, and the second shielding portions 23 corresponding to adjacent air holes 221 are spaced apart. On the one hand, the second shielding portion 23 and the first shielding portion 16 can be prepared in a same process, and on the other hand, the material of the second shielding portion 23 can be saved while providing good shielding effect, thereby saving costs.

In a possible implementation, as shown in FIGS. 17 and 18, the bezel area B further includes a dam 24 located at one side of the base plate 10, and the dam 24 is arranged in the same layer as the fourth isolation structure 22 and spaced apart from the fourth isolation structure 22.

In the above implementation, the dam 24 may be used to block outward flow of the film layer, so as to increase the preparation yield and film thickness uniformity for the film layer. Specifically, the display panel 1 may further include an organic encapsulation layer 25 and an inorganic encapsulation layer 26 located at a side of the encapsulation layer 18 away from the base plate 10. The organic encapsulation layer 25 has great flowability, and the dam 24 may be used to block the flow of the organic encapsulation layer 25 to the periphery of the display panel 1, so as to increase the preparation yield and film thickness uniformity for the organic encapsulation layer 25.

The present application further provides another display panel 1 with a first display sub-area A21, and the display panel 1 includes a base plate 10, light-emitting units 11, an isolation structure 12, and a first shielding portion 16. The number of the light-emitting units 11 is two or more, each of the light-emitting units 11 includes a first electrode 111, a light-emitting functional portion 112, and a second electrode 113 stacked along a direction away from the base plate 10, and the second electrodes 113 of adjacent light-emitting units 11 are spaced apart. The isolation structure 12 is formed at one side of the base plate 10 and including a first physical portion 121 and a first opening portion 122, the first physical portion 121 is arranged around the first opening portion 122, the first opening portion 122 exposes at least a portion of the first electrode 111 of the light-emitting unit 11, and the isolation structure 12 further includes at least one light-transmitting aperture 153 arranged in the first display sub-area A21. The first shielding portion 16 is located at one side of the base plate 10, an orthographic projection of the first shielding portion 16 on the base plate 10 overlaps an orthographic projection of the light-transmitting aperture 153 on the base plate 10, and the first shielding portion 16 has a light-transmitting structure.

The display panel 1 according to the present application includes the base plate 10, the light-emitting units 11, and the isolation structure 12. The isolation structure 12 further includes at least one light-transmitting aperture 153 arranged in the first display sub-area A21, so as to increase the light transmittance of the first display sub-area A21. The orthographic projection of the first shielding portion 16 on the base plate 10 covers the orthographic projection of the light-transmitting aperture 153 on the base plate 10. Specifically, the first shielding portion 16 may be formed between the isolation structure 12 and the base plate 10 and is in contact with the isolation structure 12. The first shielding portion 16 can effectively reduce signal interference between the base plate 10 and a film layer of the isolation structure 12 at a side away from the base plate 10. Specifically, the display panel 1 may include a touch control layer located at a side of the isolation structure 12 away from the base plate 10, the touch control layer includes a touch control electrode, and the base plate 10 is provided with a signal wiring for driving the light-emitting units 11 to display. Mutual interference between the touch control electrode and the signal wiring within the base plate 10 at the light-transmitting aperture 153 can be reduced by arranging the first shielding portion 16 at the light-transmitting aperture 153, thereby improving the performance of the display panel 1. Specifically, the isolation structure 12 includes a metal layer, which may shield positions other than the light-transmitting aperture 153, so as to reduce mutual interference between a touch control signal and a display signal.

In a possible implementation, the orthographic projection of the first shielding portion 16 on the base plate 10 covers the orthographic projection of the light-transmitting aperture 153 on the base plate 10, so as to achieve good shielding effect.

In a possible implementation, the first shielding portion 16 is electrically connected with the isolation structure 12, so as to achieve the continuity of the isolation structure 12 within the first display sub-area A21, thereby facilitating signal transmission.

In a possible implementation, the display panel 1 further includes a second display sub-area A22, the light transmittance of the first display sub-area A21 is greater than the light transmittance of the second display sub-area A22, and the first shielding portion 16 is arranged in the first display sub-area A21 and not in the second display sub-area A22. Specifically, the display panel 1 may further include a first display area A1, and the light transmittance of the first display area A1 is greater than the light transmittance of the first display sub-area A21. Specifically, the first display area A1 may be an under screen camera area. The second display sub-area A22 may be a normal display area, and the first display sub-area A21 may be a fingerprint identification area and the like.

In a possible implementation, the number of the first shielding portions 16 is two or more, the number of the light-transmitting apertures 153 is two or more, and the plurality of first shielding portions 16 and the plurality of light-transmitting apertures 153 are arranged in one-to-one correspondence. Thereby, the light-transmitting aperture 153 is shielded by the first shielding portion 16, and moreover, the plurality of first shielding portions 16 are spaced apart, which facilitates reducing material cost.

In a possible implementation, the light-emitting units 11 includes the second light-emitting units 115 located in the first display sub-area A21 and the second display sub-area A22. The isolation structure 12 includes the second isolation structures 1512 located in the first display sub-area A21 and the second display sub-area A22, the second isolation structure 1512 has a mesh structure and includes a second physical portion 151 and a second opening portion 152, the second physical portion 151 is continuously arranged as a whole layer, and the second opening portion 152 is for exposing at least a portion of the first electrode 111 of the second light-emitting unit 115. The second isolation structure 1512 can make a mask plate to be omitted during the preparation of the light-emitting units 11, improve the preparation process of the light-emitting units 11, and reduce crosstalk between adjacent light-emitting units 11.

In a possible implementation, as shown in FIG. 19, the second isolation structure 1512 includes a fifth isolation portion 154 including a second electrically insulating layer 1541 and a second electrically conductive layer 1542, the second electrically insulating layer 1541 covers at least an edge of the second electrode 113 of the second light-emitting unit 115, the second electrically conductive layer 1542 is located at a side of the second electrically insulating layer 1541 away from the base plate 10, and the second electrode 113 of the second light-emitting unit 115 and the first shielding portion 16 are electrically connected with the second electrically conductive layer 1542.

In the above implementation, the pixel defining layer 14 in the display panel 1 is omitted, while the isolation structure 12 is used to define the light-emitting unit 11. The isolation structure 12 includes the second isolation structure 1512, the second isolation structure 1512 includes the fifth isolation portion 154, the fifth isolation portion 154 includes the second electrically insulating layer 1541 and the second electrically conductive layer 1542, and the second electrically conductive layer 1542 is located at a side of the second electrically insulating layer 1541 away from the base plate 10. Herein, the second electrically insulating layer 1541 is in direct contact with the base plate 10 and the side of the first electrode 111 of the second light-emitting unit 115 away from the base plate 10, and the second electrically insulating layer 1541 covers the edge of the first electrode 111 of the second light-emitting unit 115, so as to achieve mutual electrical insulation for the first electrodes 111 of adjacent second light-emitting units 115 and protect the first electrodes 111 of the second light-emitting units 115. The second electrically conductive layer 1542 and the first shielding portion 16 are used to connect the second electrodes 113 of different second light-emitting units 115. Specifically, the second electrode 113 of the second light-emitting unit 115 is in direct contact with the sidewall of the second electrically conductive layer 1542 to achieve the electrical connection between the second electrode 113 of the second light-emitting unit 115 and the second isolation structure 1512, and the portions of the second isolation structure 1512 located at two sides of the light-transmitting aperture 153 are electrically connected through the first shielding portion 16, thereby further increasing the overall continuity of the second isolation structure 1512.

In a possible implementation, as shown in FIG. 19, the second isolation structure 1512 further includes a sixth isolation portion 155 located at a side of the fifth isolation portion 154 away from the base plate 10, and the orthographic projection of the fifth isolation portion 154 on the base plate 10 is located within the orthographic projection of the sixth isolation portion 155 on the base plate 10.

In the above implementation, the second isolation structure 1512 includes the fifth isolation portion 154 and the sixth isolation portion 155 that are stacked along a direction away from the base plate 10, and the orthographic projection of the fifth isolation portion 154 on the base plate 10 is located within the orthographic projection of the sixth isolation portion 155 on the base plate 10. Therefore, when preparing the second light-emitting units 115 of various colors, the individual film layers in the second light-emitting units 115 of one color may be formed first as a whole layer, then the second light-emitting units 115 of that color may be formed by etching at the designated second opening portions 152, and the second opening portions 152 for forming the second light-emitting units 115 of other colors are exposed. The second light-emitting units 115 of different colors may be prepared in sequence, while no mask plate is needed in the above preparation process, and further the pixel defining layer 14 and support column located at a side of the pixel defining layer 14 away from the base plate 10 for supporting a mask plate are not needed, and thus the preparation cost can be saved. The second isolation structure 1512 may be formed using a dark-colored material, so as to provide light-shading effect and prevent optical crosstalk between adjacent second light-emitting units 115.

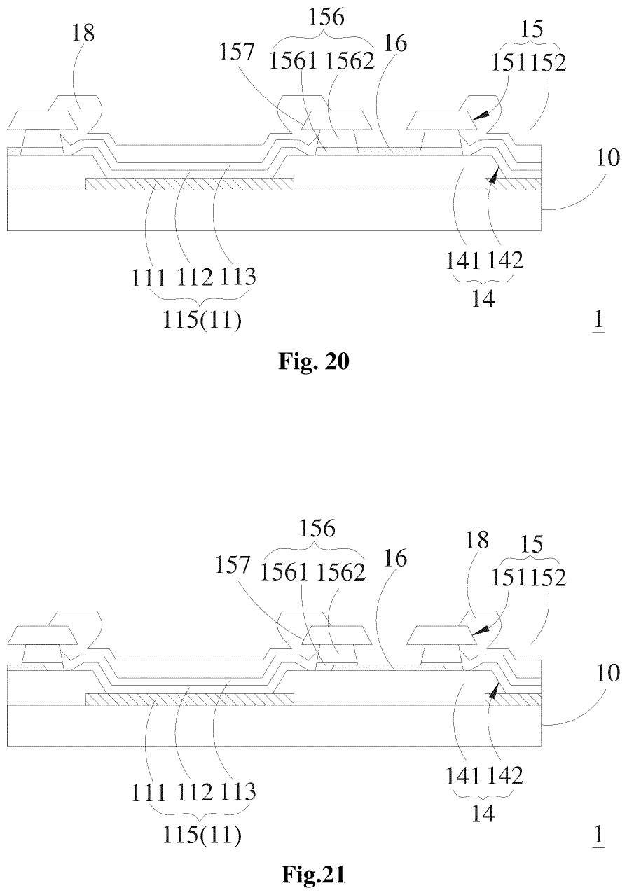

In a possible implementation, as shown in FIG. 20, the display panel 1 further includes a pixel defining layer 14 located between the first electrode 111 and the isolation structure 12, the pixel defining layer 14 includes a pixel defining portion 141 and a pixel opening 142, and the pixel openings 142 and the second opening portions 152 are arranged in one-to-one correspondence and connected respectively for accommodating the light-emitting units 11. The second isolation structure 1512 includes a seventh isolation portion 156, the seventh isolation portion 156 includes an electrically conductive material, and the first shielding portion 16 and the second electrode 113 of the second light-emitting unit 115 are connected with the seventh isolation portion 156.

In the above implementation, the display panel 1 includes the pixel defining layer 14 and the isolation structure 12 located at a side of the pixel defining layer 14 away from the base plate 10. The pixel-defining layer 14 is used to define the light-emitting unit 11. The second isolation structure 1512 includes the seventh isolation portion 156 in direct contact with a side surface of the pixel defining layer 14 away from the base plate 10, the seventh isolation portion 156 includes an electrically conductive material, and the second electrode 113 of the second light-emitting unit 115 and the first shielding portion 16 are connected with the seventh isolation portion 156, so as to achieve the electrical connection for the second electrodes 113 of different second light-emitting units 115.

In a possible implementation, as shown in FIG. 20, the seventh isolation portion 156 includes a first functional layer 1561 and a second functional layer 1562 located at a side of the first functional layer 1561 away from the base plate 10, the first functional layer 1561 includes an electrically conductive material, and the first shielding portion 16 and the second electrode 113 of the second light-emitting unit 115 are connected with the first functional layer 1561.

In the above implementation, the material of the first functional layer 1561 may be a metal, such as molybdenum, and the material of the second functional layer 1562 may be a metal, such as aluminum. The first functional layer 1561 may protect the second functional layer 1562 and prevent oxidation of the second functional layer 1562 due to water and oxygen from the side corresponding to the base plate 10.

In a possible implementation, as shown in FIG. 20, the second isolation structure 1512 further includes an eighth isolation portion 157 located at a side of the seventh isolation portion 156 away from the base plate 10, and the orthographic projection of the seventh isolation portion 156 on the base plate 10 is located within the orthographic projection of the eighth isolation portion 157 on the base plate 10.

In the above implementation, the second isolation structure 1512 includes the seventh isolation portion 156 and the eighth isolation portion 157, and the orthographic projection of the seventh isolation portion 156 on the base plate 10 is located within the orthographic projection of the eighth isolation portion 157 on the base plate 10. Therefore, when preparing the second light-emitting units 115 of various colors, the individual film layers in the second light-emitting units 115 of one color may be formed first as a whole layer, then the second light-emitting units 115 of that color may be formed by etching at the designated second opening portions 152, and the second opening portions 152 for forming the second light-emitting units 115 of other colors are exposed. The second light-emitting units 115 of different colors may be prepared in sequence, while no mask plate is needed in the above preparation process, and further the pixel defining layer 14 and support column located at a side of the pixel defining layer 14 away from the base plate 10 for supporting a mask plate are not needed, and thus the preparation cost can be saved. The second isolation structure 1512 may be formed using a dark-colored material, so as to provide light-shading effect and prevent optical crosstalk between adjacent second light-emitting units 115.

In a possible implementation, the first shielding portion 16 and the first functional layer 1561 are distributed along a direction parallel to a plane where the base plate 10 is located and are in contact with each other, and the orthographic projection of the second functional layer 1562 on the base plate 10 covers a portion of the orthographic projection of the first shielding portion 16 on the base plate 10; or as shown in FIG. 20, the orthographic projection of the second functional layer 1562 on the base plate 10 is spaced apart from the orthographic projection of the first shielding portion 16 on the base plate 10.

In the above implementation, the first shielding portion 16 and a sidewall of the first functional layer 1561 are in contact, and thus the first shielding portion 16 and the first functional layer 1561 are electrically connected. A portion of the first shielding portion 16 is located between the second functional layer 1562 and the pixel defining layer 14, i.e., the orthographic projection of the second functional layer 1562 on the base plate 10 covers a portion of the orthographic projection of the first shielding portion 16 on the base plate 10, so as to protect the contact portion between the first functional layer 1561 and the first shielding portion 16 by the second functional layer 1562, and reduce the effect of the subsequent process on the contact portion. Moreover, if the material of the second functional layer 1562 is a metal, the contact resistance between the first shielding portion 16 and the first functional layer 1561 can be further reduced.

In a possible implementation, as shown in FIG. 21, the first shielding portion 16 is in contact with a side of the pixel defining layer 14 away from the base plate 10, and the first functional layer 1561 covers an edge of the first shielding portion 16; the orthographic projection of the second functional layer 1562 on the base plate 10 covers a portion of the orthographic projection of the first shielding portion 16 on the base plate 10. Therefore, the first shielding portion 16 and the first functional layer 1561 can be electrically connected, and the contact portion between the first functional layer 1561 and the first shielding portion 16 can be protected by the second functional layer 1562.

In the above implementation, the first shielding portion 16 is formed at a side of the pixel defining layer 14 away from the base plate 10, and the first functional layer 1561 is formed at a side of the first shielding portion 16 away from the base plate 10, i.e., the first shielding portion 16 is prepared first, followed by the first functional layer 1561. The first functional layer 1561 covers the edge of the first shielding portion 16, i.e., the first functional layer 1561 is in contact with a sidewall of the first shielding portion 16 at a side towards the second opening portion 152. Moreover, the first functional layer 1561 is in contact with a side surface of the first shielding portion 16 away from the base plate 10, which can increase the contact area between the first functional layer 1561 and the first shielding portion 16, so as to improve the connection stability and reduce the contact resistance between the first functional layer 1561 and the first shielding portion 16.

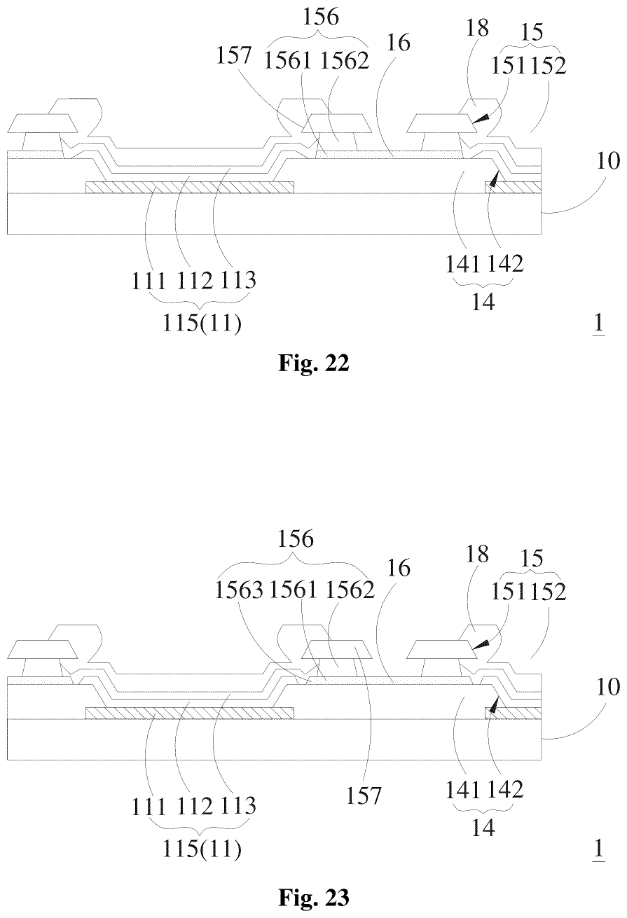

In a possible implementation, as shown in FIG. 22, the first shielding portion 16 and the first functional layer 1561 are of a same material and form a one-piece structure.

In the above implementation, the first shielding portion 16 and the first functional layer 1561 are prepared in a same process and form a one-piece structure, and thus the connection stability between the first shielding portion 16 and the first functional layer 1561 is stronger, and the preparation process can be saved, thereby reducing the preparation cost. In such cases, the material of the first functional layer 1561 is the same as the material of the first shielding portion 16, both of which are transparent electrically conductive materials.

In the above implementation, as shown in FIG. 23, one end of the first functional layer 1561 close to the second opening portion 152 includes a second extension portion 1563 extending beyond the second functional layer 1562, and the orthographic projection of the second extension portion 1563 on the base plate 10 is located within the orthographic projection of the eighth isolation portion 157 on the base plate 10.

In the above implementation, with the second extension portion 1563 of the first functional layer 1561, a preset distance is between an end of the second functional layer 1562 close to the second opening portion 152 and an end of the first functional layer 1561 close to the second opening portion 152, the contact area between the second electrode 113 of the second light-emitting unit 115 and the first functional layer 1561 can be further increased, thereby improving the stability of electrical connection between the second electrode 113 of the second light-emitting unit 115 and the second isolation structure 1512, and also reducing contact resistance.

In a possible implementation, the display panel 1 further includes a touch control layer located at a side of the isolation structure 12 away from the base plate 10, and the first shielding portion 16 is located between the base plate 10 and the touch control layer.

Specifically, the base plate 10 includes a drive circuit layer, the first shielding portion 16 is located between the drive circuit layer and the first electrode 111, the first shielding portions 16 are in one-to-one correspondence with the second light-emitting units 115, adjacent first shielding portions 16 are spaced apart, and the first electrode 111 is connected with the first shielding portion 16.

Specifically, the drive circuit layer includes a first drive circuit located in the first display sub-area A21, the first electrode of 111 the second light-emitting unit 115 is connected with the first drive circuit through the first shielding portion 16; the first shielding portion 16 includes a transparent electrically conductive material.

In the above implementation, the first shielding portion 16 may be not in contact with the isolation structure 12, but is arranged within the base plate 10, which is not limited herein.

In a possible implementation, as shown in FIGS. 2, 4, and 5, the display panel includes a first display area A1, and the display panel further includes: a base plate; a plurality of light-emitting units 11 each including a first electrode 111, a light-emitting functional portion 112, and a second electrode 113 stacked along a direction away from the base plate, second electrodes 113 of adjacent light-emitting units 11 being spaced apart, and the plurality of light-emitting units 11 including at least one first light-emitting unit 114 located in the first display area A1; an isolation structure 12 formed at one side of the base plate and including a plurality of first isolation structures 120 spaced apart within the first display area A1, the first isolation structure 120 including a first physical portion 121 and a first opening portion 122, the first physical portion 121 being arranged around the first opening portion 122, the first opening portion 122 exposing at least a portion of the first electrode 111 of the first light-emitting unit 114; and the first isolation structure 120 having an annular structure arranged around at least one first light-emitting unit 114.

The content of FIGS. 2, 4 and 5 have been described above and will not be repeated herein.

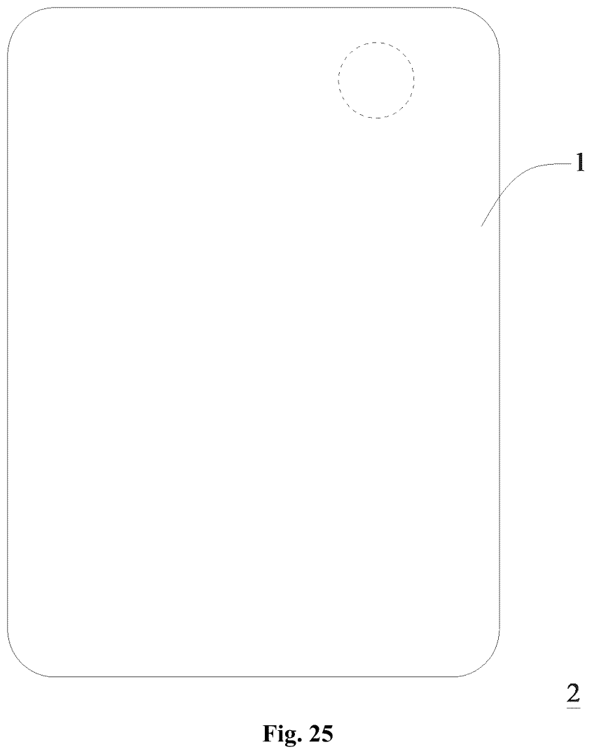

The present application further provides a display apparatus 2, as shown in FIG. 25, including any of the display panels 1 according to the above implementation of the present application.

Since the display apparatus 2 according to the present application includes any of the display panels 1 according to the above implementation, the display apparatus 2 according to the present application has the beneficial effect of any of the display panels 1 according to the above implementation, which will not be repeated herein.

The display apparatus 2 in the embodiments of the present application includes, but is not limited to, a cellular phone, a Personal Digital Assistant (PDA), a tablet computer, an e-book, a television, an entrance guard, a smart fixed-line phone, a console, and other apparatus with display function.

The above embodiments of the present application do not exhaustively describe all the details, nor do they limit the present application to the specific embodiments as described. Obviously, according to the above description, many modifications and changes can be made. These embodiments are selected and particularly described in the specification to better explain the principles and practical applications of the present application, so that a person skilled in the art is able to utilize the present application and make modifications based on the present application. The present application is limited only by the claims and the full scope and equivalents of the claims.

What is claimed is:

1. A display panel having a first display area, the display panel comprising:
a base plate;
a plurality of light-emitting units each comprising a first electrode, a light-emitting functional portion, and a second electrode stacked along a direction away from the base plate, the second electrodes of adjacent light-emitting units being spaced apart, and the plurality of light-emitting units comprising at least one first light-emitting unit located in the first display area;
an isolation structure formed at one side of the base plate and comprising a plurality of first isolation structures spaced apart within the first display area, the first isolation structure comprising a first physical portion and a first opening portion, the first physical portion being arranged around the first opening portion, the first opening portion exposing at least a portion of the first electrode of the first light-emitting unit, and the second electrode of the first light-emitting unit being electrically connected with the first isolation structure; and
a light-transmitting connection portion, at least a portion of adjacent first isolation structures being electrically connected through the light-transmitting connection portion.

2. The display panel according to claim 1, wherein the light-transmitting connection portion has a mesh structure continuously arranged as a whole layer, and the light-transmitting connection portion comprises a via opposite to the first opening portion;
the light-transmitting connection portion is located between the first isolation structures, and an orthographic projection of the light-transmitting connection portion on the base plate is spaced apart from an orthographic projection of the light-emitting unit on the base plate.

3. The display panel according to claim 2, wherein the display panel further comprises a touch control layer located at a side of the isolation structure away from the base plate, and the light-transmitting connection portion being located between the base plate and the touch control layer.

4. The display panel according to claim 1, wherein the light-transmitting connection portion is in the form of a strip and arranged between two adjacent first isolation structures, one end of the light-transmitting connection portion is electrically connected with one of the first isolation structures, and the other end of the light-transmitting connection portion is electrically connected with the other of the first isolation structures.

5. The display panel according to claim 4, wherein an orthographic projection of the light-transmitting connection portion on the base plate extends along a straight line, or the orthographic projection of the light-transmitting connection portion on the base plate extends along a curve.

6. The display panel according to claim 1, wherein the first isolation structure comprises a first isolation portion, the first isolation portion comprises a first electrically insulating layer and a first electrically conductive layer, the first electrically insulating layer covers at least an edge of the first electrode of the first light-emitting unit, the first electrically conductive layer is located at a side of the first electrically insulating layer away from the base plate, and the second electrode of the first light-emitting unit and the light-transmitting connection portion are electrically connected with the first electrically conductive layer.

7. The display panel according to claim 6, wherein the first isolation structure further comprises a second isolation portion located at a side of the first isolation portion away from the base plate, and an orthographic projection of the first isolation portion on the base plate is located within an orthographic projection of the second isolation portion on the base plate, and
the first isolation structure has an annular structure arranged around at least one first light-emitting unit.

8. The display panel according to claim 1, further comprising a pixel defining layer located between the first electrode and the isolation structure, the pixel defining layer comprising a pixel defining portion and a pixel opening, and the pixel openings and the first opening portions being arranged in one-to-one correspondence and connected respectively for accommodating the light-emitting units; and
the first isolation structure comprising a third isolation portion comprising an electrically conductive material, and the light-transmitting connection portion and the second electrode of the first light-emitting unit being connected with the third isolation portion;
wherein the third isolation portion comprises a first layer and a second layer located at a side of the first layer away from the base plate, the first layer comprises an electrically conductive material, and the light-transmitting connection portion and the second electrode of the first light-emitting unit are connected with the first layer.

9. The display panel according to claim 8, wherein the first isolation structure further comprises a fourth isolation portion located at a side of the third isolation portion away from the base plate, and an orthographic projection of the third isolation portion on the base plate is located within an orthographic projection of the fourth isolation portion on the base plate.

10. The display panel according to claim 9, wherein the light-transmitting connection portion and the first layer are distributed along a direction parallel to a plane where the base plate is located and are in contact with each other, and an orthographic projection of the second layer on the base plate covers a portion of an orthographic projection of the light-transmitting connection portion on the base plate; or
the light-transmitting connection portion is in contact with a side of the pixel defining layer away from the base plate, and the first layer covers an edge of the light-transmitting connection portion; or
the light-transmitting connection portion and the first layer are of a same material and form a one-piece structure.

11. The display panel according to claim 10, wherein one end of the first layer close to the first opening portion comprises a first extension portion extending beyond the second layer, and an orthographic projection of the first extension portion on the base plate is located within an orthographic projection of the fourth isolation portion on the base plate.

12. The display panel according to claim 1, wherein the display panel further comprises a second display area, the light-emitting units further comprise a second light-emitting unit located in the second display area, and a light transmittance of the second display area is less than a light transmittance of the first display area;
the isolation structure further comprises a second isolation structure located within the second display area and having a mesh structure, the second isolation structure comprises a second physical portion and a second opening portion, the second physical portion is continuously arranged as a whole layer, and the second opening portion is for exposing at least a portion of the first electrode of the second light-emitting unit.

13. The display panel according to claim 12, wherein an area of an orthographic projection of the first light-emitting unit on the base plate is less than an area of an orthographic projection of the second light-emitting unit of a same color on the base plate, and a spacing between adjacent first light-emitting units is greater than a spacing between adjacent second light-emitting units.

14. The display panel according to claim 12, wherein within the second display area, the second electrode of the second light-emitting unit is electrically connected with the second physical portion; the second isolation structure further comprises a light-transmitting aperture located between at least a portion of adjacent second opening portions; the second display area comprises a first display sub-area and a second display sub-area, the light transmittance of the first display area is greater than a light transmittance of the first display sub-area, the light transmittance of the first display sub-area is greater than a light transmittance of the second display sub-area, the light-transmitting aperture is arranged on the second isolation structure within the first display sub-area; the display panel further comprises a first shielding portion arranged at one side of the base plate, an orthographic projection of the first shielding portion on the base plate covers an orthographic projection of the light-transmitting aperture on the base plate, the first shielding portion has a light-transmitting structure; the first shielding portion is arranged in the same layer as the light-transmitting connection portion; the second electrode of the first light-emitting unit is electrically connected with the second electrode of the second light-emitting unit through the light-transmitting connection portion; and the first physical portion of the first isolation structure is electrically connected with the second physical portion of the second isolation structure through the light-transmitting connection portion.

15. The display panel according to claim 12, wherein the base plate comprises a first drive circuit located in the first display area, and the first electrode of the first light-emitting unit is connected with the first drive circuit through a first electrode wiring; the first electrode wiring comprises a transparent electrically conductive material.

16. The display panel according to claim 12, wherein the display panel further comprises a transition area located between the first display area and the second display area, the light-emitting units comprise a third light-emitting unit located in the transition area, the base plate comprises a second drive circuit located in the transition area, the first electrode of the third light-emitting unit is connected with the second driving circuit through a second electrode wiring, and the first electrode of the first light-emitting unit is connected with the second drive circuit through the second electrode wiring.

17. The display panel according to claim 16, wherein the isolation structure further comprises a third isolation structure located in the transition area, the second electrode of the third light-emitting unit is connected with the third isolation structure; the third isolation structure and the second isolation structure are arranged continuously, and the third isolation structure is electrically connected with the first isolation structure through the light-transmitting connection portion; or
the third isolation structure has the same structure as the first isolation structure, and the third isolation structure is electrically connected with the second isolation structure through the light-transmitting connection portion.

18. The display panel according to claim 14, wherein the display panel further comprises a bezel area, the isolation structure further comprises a fourth isolation structure located within the bezel area, the fourth isolation structure and the second isolation structure are arranged continuously, and the fourth isolation structure comprises an air hole.

19. The display panel according to claim 18, wherein the air hole is arranged in the same or different manner as the light-transmitting aperture; the bezel area comprises a second shielding portion and a dam, the second shielding portion is arranged at one side of the base plate, the second shielding portion is arranged in the same layer as the first shielding portion, an orthographic projection of the second shielding portion on the base plate covers an orthographic projection of the air hole on the base plate, second shielding portions and air holes are arranged in one-to-one correspondence, the second shielding portions corresponding to adjacent air holes are spaced apart; and the dam is located at one side of the fourth isolation structure in a direction from the second display area to the bezel area.

20. A display panel with a first display sub-area, the display panel comprising:
a base plate;
a plurality of light-emitting units each comprising a first electrode, a light-emitting functional portion, and a second electrode stacked along a direction away from the base plate, second electrodes of adjacent light-emitting units being spaced apart;
an isolation structure formed at one side of the base plate and comprising a first physical portion and a first opening portion, the first physical portion being arranged around the first opening portion, the first opening portion exposing at least a portion of the first electrode of the light-emitting unit, the isolation structure further comprising at least one light-transmitting aperture arranged in the first display sub-area; and
a first shielding portion located at one side of the base plate, an orthographic projection of the first shielding portion on the base plate overlapping an orthographic projection of the light-transmitting aperture on the base plate, and the first shielding portion having a light-transmitting structure.

21. The display panel according to claim 20, wherein
the orthographic projection of the first shielding portion on the base plate covers the orthographic projection of the light-transmitting aperture on the base plate; and the first shielding portion is electrically connected with the isolation structure.

22. The display panel according to claim 20, wherein
the display panel further comprises a second display sub-area, a light transmittance of the first display sub-area is greater than a light transmittance of the second display sub-area, the first shielding portion is arranged in the first display sub-area and not in the second display sub-area; the display panel comprises a plurality of first shielding portions and a plurality of light-transmitting apertures, and the plurality of first shielding portions and the plurality of light-transmitting apertures are arranged in one-to-one correspondence.

23. The display panel according to claim 22, wherein
the light-emitting units comprise second light-emitting units located in the first display sub-area and the second display sub-area; and
the isolation structure comprises a plurality of second isolation structures located in the first display sub-area and the second display sub-area, the second isolation structure has a mesh structure and comprises a second physical portion and a second opening portion, and the second opening portion is for exposing at least a portion of the first electrode of the second light-emitting unit.

24. The display panel according to claim 23, wherein
the second isolation structure comprises a fifth isolation portion comprising a second electrically insulating layer and a second electrically conductive layer, the second electrically insulating layer covers at least an edge of the second electrode of the second light-emitting unit, the second electrically conductive layer is located at a side of the second electrically insulating layer away from the base plate, and the second electrode of the second light-emitting unit and the first shielding portion are electrically connected with the second electrically conductive layer; the second isolation structure further comprises a sixth isolation portion located at a side of the fifth isolation portion away from the base plate, and an orthographic projection of the fifth isolation portion on the base plate is located within an orthographic projection of the sixth isolation portion on the base plate.

25. The display panel according to claim 23, further comprising a pixel defining layer located between the first electrode and the isolation structure, the pixel defining layer comprising a pixel defining portion and a pixel opening, and pixel openings and second opening portions being arranged in one-to-one correspondence and connected respectively for accommodating the light-emitting units; and
the second isolation structure comprising a seventh isolation portion and an eighth isolation portion, the seventh isolation portion comprising an electrically conductive material, and the first shielding portion and the second electrode of the second light-emitting unit being connected with the seventh isolation portion; and
the seventh isolation portion comprising a first functional layer and a second functional layer located at a side of the first functional layer away from the base plate, the first functional layer comprising an electrically conductive material, and the first shielding portion and the second electrode of the second light-emitting unit being connected with the first functional layer; the eighth isolation portion being located at a side of the seventh isolation portion away from the base plate, and an orthographic projection of the seventh isolation portion on the base plate being located within an orthographic projection of the eighth isolation portion on the base plate.

26. The display panel according to claim 25, wherein the first shielding portion and the first functional layer are distributed along a direction parallel to a plane where the base plate is located and are in contact with each other, and an orthographic projection of the second functional layer on the base plate covers a portion of the orthographic projection of the first shielding portion on the base plate; or
the first shielding portion is in contact with a side of the pixel defining layer away from the base plate, and the first functional layer covers an edge of the first shielding portion; or
the first shielding portion and the first functional layer are of a same material and form a one-piece structure;
one end of the first functional layer close to the second opening portion comprises a second extension portion extending beyond the second functional layer, and an orthographic projection of the second extension portion on the base plate is located within the orthographic projection of the eighth isolation portion on the base plate.

27. The display panel according to claim 23, further comprising a touch control layer located at a side of the isolation structure away from the base plate, and the first shielding portion being located between the base plate and the touch control layer.

28. The display panel according to claim 23, wherein the base plate comprises a drive circuit layer, the first shielding portion is located between the drive circuit layer and the first electrode, the first shielding portions are in one-to-one correspondence with the second light-emitting units, adjacent first shielding portions are spaced apart, and the first electrode is connected with the first shielding portion; the drive circuit layer comprises a first drive circuit located in the first display sub-area, the first electrode of the second light-emitting unit is connected with the first drive circuit through the first shielding portion; the first shielding portion comprises a transparent electrically conductive material.

29. The display panel according to claim 23, wherein
the display panel further comprises a bezel area, the isolation structure further comprises a fourth isolation structure located within the bezel area, the fourth isolation structure and the second isolation structure are arranged continuously, and the fourth isolation structure comprises an air hole.
